(19) United States
(12) Patent Application Publication
(10) Pub. No.: US 2015/0332995 A1
(43) Pub. Date: Nov. 19, 2015

(54) ELECTRONIC DEVICE INCLUDING COMPONENTS IN COMPONENT RECEIVING CAVITY AND RELATED METHODS

(71) Applicant: STMICROELECTRONICS PTE LTD, Singapore (SG)

(72) Inventors: Kim-Yong GOH, Singapore (SG); Wing Shenq Wong, Singapore (SG)

(73) Assignee: STMICROELECTRONICS PTE LTD, Singapore (SG)

(21) Appl. No.: 14/278,458

(22) Filed: May 15, 2014

(51) Int. Cl. H01L 23/498; H01L 23/31; H05K 1/18

(52) U.S. Cl. CPC H01L 23/49838; H05K 1/181; H01L 23/315; H05K 2201/10515; H05K 2201/10522; H05K 2201/10689; H05K 2201/10977; H05K 2201/10962

(57) ABSTRACT

An electronic device may include a surface mount integrated circuit (IC) package to be attached to a printed circuit board (PCB). The surface mount IC package may include at least one IC and an encapsulating material surrounding the at least one IC and having a component receiving cavity defined therein on a bottom surface thereof to be positioned adjacent the PCB. The surface mount IC package may also include electrical leads coupled to the at least one IC and extending outwardly from the encapsulating material to be coupled to the PCB. The electronic device may also include at least one electronic component carried within the component receiving cavity and that includes electrical contacts to be coupled to the PCB.

### TECHNICAL FIELD

The present application is directed to electronic devices, and more particularly, to integrated circuit packages and related methods.

### BACKGROUND

As the functionality of an electronic device increases, so too does the desire for the electronic device to maintain a relatively small size. One way of reducing the overall size of an electronic device is to reduce the size of the electronic components or integrated circuits carried by a printed circuit board (PCB) of the electronic device. The type of packaging may be selected to increase usage of the available space on the PCB.

Referring to FIG. 1, one type of packaging is a quad flat package (QFP), which is a type of surface mount integrated circuit (IC) package 10 that includes gull wing shaped electrical leads 11 that extend outwardly from an encapsulating material 15 for coupling to a PCB. Illustratively, the QFP 10 includes a die pad 12 or paddle and an IC 13 carried by the die pad. An adhesive layer 16 is between the IC 13 and the die pad 12. A plurality of bond wires 14 couple the IC 13 to a lead frame, which defines after trimming and singulation, the gull wing shaped electrical leads 11. An encapsulating material 16 surrounds the IC 13, the die pad 12, and the bond wires 14.

### SUMMARY

An electronic device may include a surface mount integrated circuit (IC) package to be attached to a printed circuit board (PCB). The surface mount IC package may include at least one IC and an encapsulating material surrounding the at least one IC and having a component receiving cavity defined therein on a bottom surface thereof to be positioned adjacent the PCB. The surface mount IC package may also include a plurality of electrical leads coupled to the at least one IC and extending outwardly from the encapsulating material to be coupled to the PCB. The electronic device may also include at least one electronic component carried within the component receiving cavity and comprising a plurality of electrical contacts to be coupled to the PCB. Accordingly, the electronic device may provide increased space savings since the electronic components that would otherwise be carried by the PCB spaced from the surface mount IC package are carried within the component receiving cavity.

The plurality of electrically conductive leads may each have a gull-wing shape, for example. The plurality of electrical contacts and the plurality of electrical leads may be aligned along a common seating plane to facilitate mounting on the PCB.

The at least one electronic component may extend outwardly beyond adjacent portions of the encapsulating material, for example. The at least one IC and the at least one electronic component may not be electrically coupled within the surface mount IC package in some embodiments.

The electronic device may also include a fill material filling spaces between the at least one electronic component and adjacent portions of the encapsulating material. The electronic device may also include an adhesive layer between the at least one electronic component and adjacent portions of the encapsulating material, for example.

The at least one electronic component may include a plurality of electronic components. The at least one electronic component may include at least one surface mount device (SMD) component, for example. The surface mount IC package may include a plurality of bond wires coupling respective ones of the plurality of electrically conductive leads to the IC.

A method aspect is directed to a method of making an electronic device. The method may include forming a surface mount integrated circuit (IC) package to be attached to a printed circuit board (PCB). Forming the surface mount IC may include forming an encapsulating material surrounding at least one IC, and having a component receiving cavity in a bottom surface thereof to be positioned adjacent the PCB, and coupling a plurality of electrical leads to the at least one IC and extending outwardly from the encapsulating material to be coupled to the PCB. The method may also include coupling at least one electronic component within the component receiving cavity. The at least one electronic component may include a plurality of electrical contacts to be coupled to the PCB.

### BRIEF DESCRIPTION OF THE DRAWINGS

FIG. 1 is schematic cross-sectional view of a quad flat package in accordance with the prior art.

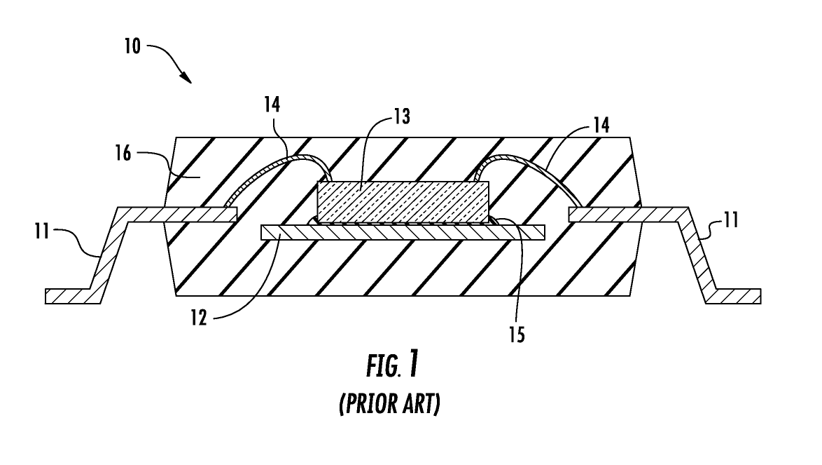

FIG. 2 is a schematic cross-sectional view of an electronic device in accordance with an embodiment.

FIGS. 3a-3e are schematic diagrams illustrating a method of making the electronic device of FIG. 2.

### DETAILED DESCRIPTION

The embodiments will now be described more fully hereinafter with reference to the accompanying drawings, in which preferred embodiments are shown. The embodiments may, however, be in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

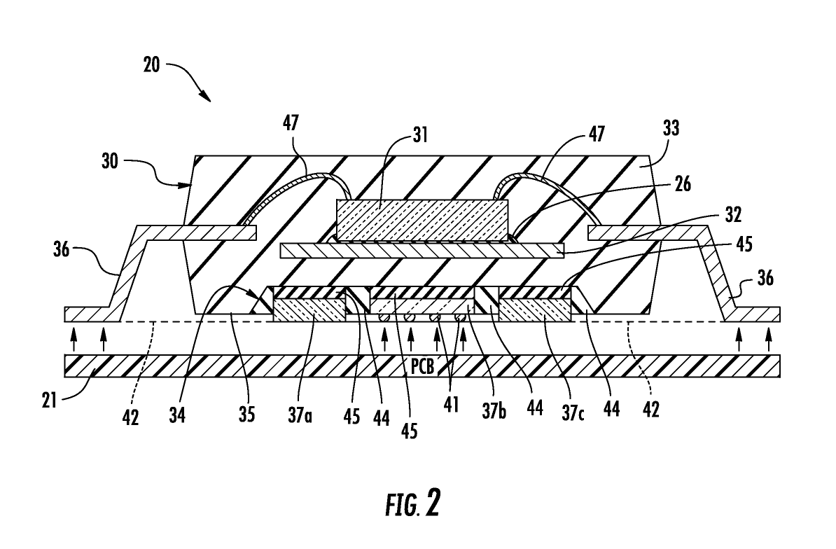

Referring now to FIG. 2, an electronic device 20 includes a surface mount integrated circuit (IC) package 30 to be attached to a printed circuit board (PCB) 21. The surface mount IC package 30 includes an IC 31 or IC die carried by a die pad 32 or die paddle. An adhesive layer 26 is between the IC 31 and the die pad 32. Of course, while one IC is illustrated, more than one IC may be used in other embodiments.

An encapsulating material 33 surrounds the IC 31. The encapsulating material 33 has a component receiving cavity 34 defined therein on a bottom surface 35 thereof to be positioned adjacent the PCB 21. The encapsulating material 33 may be a mold compound, for example.

Electrical leads 36 are coupled to the IC 31 and extend outwardly from the encapsulating material 33, and more particularly the periphery of the encapsulating material, and are coupled to the PCB 21. Each of the electrical leads 36 has a gull-wing shape. As will be appreciated by those skilled in the art, the surface mount IC package 30 is a quad flat package (QFP) structure.

In the illustrated embodiment, the electrical leads 36 are sized so that the surface mount IC package 30, and more particularly, the encapsulating material 33 is spaced from the PCB 21 when coupled thereto. In other embodiments the surface mount IC package 30 may sit directly against the PCB 21. Bond wires 47 couple respective ones of the electrical leads 36 to the IC 31.

Electronic components 37a-37c are illustratively carried within the component receiving cavity 34 and extend outwardly beyond adjacent portions of the encapsulating material 33. The electronic components 37a-37c are illustratively surface mount device (SMD) components. Of course, the electronic components 37a-37c may be other mounting or packaging types. Additionally, each of the electronic components 37a-37c may be a different packaging type.

The electronic components 37a-37c are mechanically coupled to the encapsulating material 33 within the component receiving cavity 34 by a adhesive layer 45. In other words, the adhesive layer 45 is between the electronic components 37a-37c and adjacent portions of the encapsulating material 33. The adhesive layer 45 may be a die attach film, for example.

Each electronic component includes electrical contacts 41 that are coupled to the PCB 21. The electrical contacts 41 and the electrical leads 36 are aligned along a common seating plane 42. Each electronic component 37a-37c is not electrically coupled within the surface mount IC package 30 in the illustrated embodiment. In other words, the electronic components 37a-37c are electrically isolated from the IC 31 within the surface mount IC package 30. Of course, the electronic components 37a-37c may be electrically coupled via the PCB 21 or other coupling arrangement outside of the surface mount IC package 30 to the IC 31.

A fill material 44 fills the spaces between the electronic components 37a-37c and adjacent or opposing portions of the encapsulating material 33. The fill material 44 may be an underfill, for example, and may be flush with the bottom surface 35 of the encapsulating material 33.

A method aspect is directed to a method of making an electronic device 20. The method includes forming a surface mount integrated circuit (IC) package 30 to be attached to a printed circuit board (PCB) 21. Forming the surface mount IC package 30 includes forming an encapsulating material 33 surrounding at least one IC 31 and having a component receiving cavity 34 in a bottom surface 35 thereof to be positioned adjacent the PCB 21, and coupling electrical leads 36 to the at least one IC and extending outwardly form the encapsulating material to be coupled to the PCB 21. The method also includes coupling at least one electronic component 37a-37c within the component receiving cavity 35. The at least one electronic component 37a-37c may include a plurality of electrical contacts 41 to be coupled to the PCB 21.

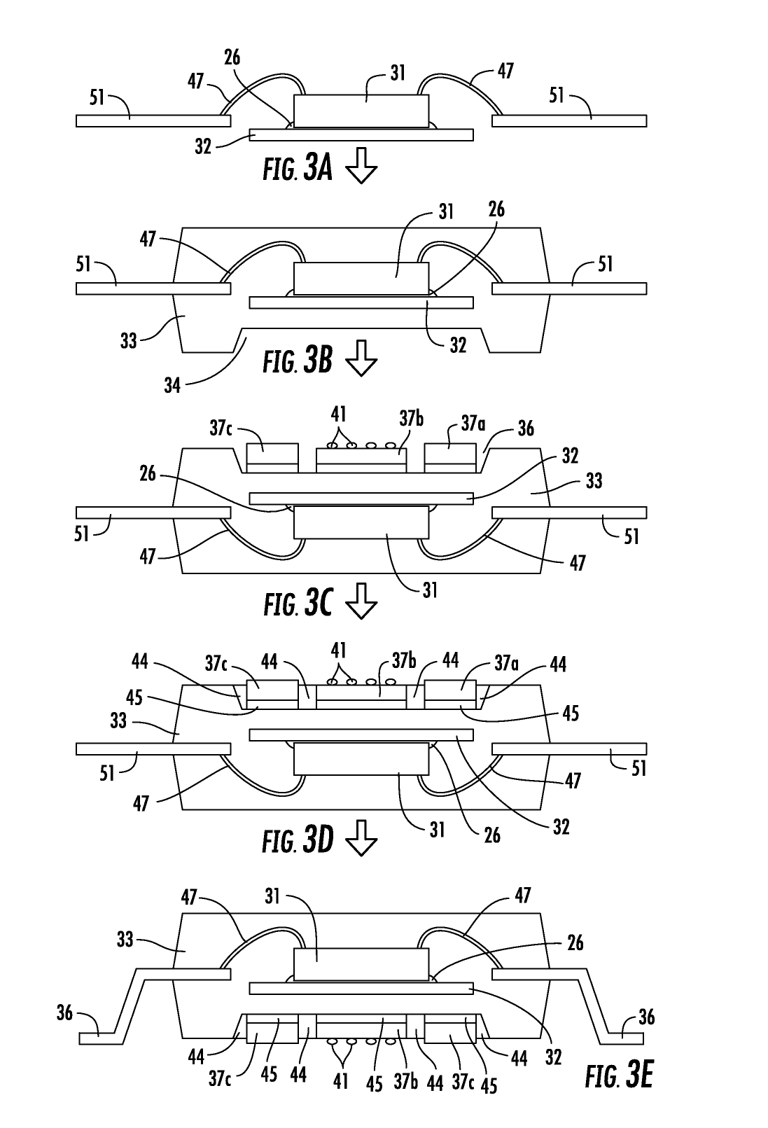

A more detailed method aspect is now described with additional reference to FIGS. 3a-3e. Referring to FIG. 3a, the method includes forming a surface mount IC package by attaching an IC 31 to an IC die pad 32 via an adhesive layer 26, and coupling bond wires 47 between the IC and a leadframe 51. It should be noted that while a single surface mount IC package 30 is illustrated, many surface mount IC packages may be formed as will be appreciated by those skilled in the art.

The encapsulating material 33 is formed to surround the IC 31, the die pad 32, and the bond wires 47. The encapsulating material 33 is also formed to have a component receiving cavity 34 on a bottom surface 35 thereof (FIG. 3b). A laser marking, not shown, may be provided on a bottom surface of the component receiving cavity 34 and which may be particularly advantageous for mounting a surface mount device (SMD) using a pick-and-place technique as will be appreciated by those skilled in the art.

The surface mount IC package 30 is inverted and electronic components 37a-37c, for example, surface mount devices are attached to the encapsulating material 33 within the component receiving cavity 34 via an adhesive layer 45 (FIG. 3c). The adhesive layer 45 may include a die attach film, for example. Of course, the electronic components 37a-37c may be attached using another bonding or attaching technique as will be appreciated by those skilled in the art.

A fill material 44, for example, an underfill material, is dispensed in the component receiving cavity 35 and to be flush with the bottom of the encapsulating material 33 or surface mount IC package 30 (FIG. 3d). The electronic device 20 is trimmed, and formed (FIG. 3e). More particularly, singulation is performed so that the electrical leads 36 are formed to have a gull-wing shape from the leadframe 51.

As will be appreciated by those skilled in the art, the electronic device 20 may be particularly advantageous for increased space-savings, for example, when the electronic device is carried in a space-limited housing. Particularly, the space that defines the component receiving cavity 34 is typically unused, and by mounting electronic components 37a-37c within the component receiving cavity, space that is otherwise occupied by the electronic components may be freed up for other or additional components, or to reduce the overall size of a host device. Additionally, the electrical contacts 41 and the electrical leads being aligned in the common seating plane 42 may advantageously increase ease in mounting to the PCB 21.

Many modifications and other embodiments will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. An electronic device comprising:
a surface mount integrated circuit (IC) package to be attached to a printed circuit board (PCB) and comprising
at least one IC,
an encapsulating material surrounding said at least one IC and having a component receiving cavity defined therein on a bottom surface thereof to be positioned adjacent the PCB, and
a plurality of electrical leads coupled to said at least one IC and extending outwardly from said encapsulating material to be coupled to the PCB; and
at least one electronic component carried within the component receiving cavity and comprising a plurality of electrical contacts to be coupled to the PCB.

2. The electronic device of claim 1 wherein said plurality of electrical leads each has a gull-wing shape.

3. The electronic device of claim 1 wherein said plurality of electrical contacts and said plurality of electrical leads are aligned along a common seating plane.

4. The electronic device of claim 1 wherein said at least one electronic component extends outwardly beyond adjacent portions of said encapsulating material.

5. The electronic device of claim 1 wherein said at least one IC and said at least one electronic component are not electrically coupled within said surface mount IC package.

6. The electronic device of claim 1 further comprising a fill material filling spaces between said at least one electronic component and adjacent portions of said encapsulating material.

7. The electronic device of claim 1 further comprising an adhesive layer between said at least one electronic component and adjacent portions of said encapsulating material.

8. The electronic device of claim 1 wherein said at least one electronic component comprises a plurality of electronic components.

9. The electronic device of claim 1 wherein said at least one electronic component comprises at least one surface mount device (SMD) component.

10. The electronic device of claim 1 wherein said surface mount IC package comprises a plurality of bond wires coupling respective ones of said plurality of electrically conductive leads to said at least one IC.

11. An electronic device comprising:
a surface mount integrated circuit (IC) package to be attached to a printed circuit board (PCB) and comprising
at least one IC,
an encapsulating material surrounding said at least one IC and having a component receiving cavity defined therein on a bottom surface thereof to be positioned adjacent the PCB, and
a plurality of electrical leads coupled to said at least one IC and extending outwardly from said encapsulating material to be coupled to the PCB, said plurality of electrical leads each having a gull-wing shape; and
at least one electronic component carried within the component receiving cavity and comprising a plurality of electrical contacts to be coupled to the PCB and aligned in a common seating plane with said at plurality of electrical leads.

12. The electronic device of claim 11 wherein said at least one electronic component extends outwardly beyond adjacent portions of said encapsulating material.

13. The electronic device of claim 11 wherein said IC and said at least one electronic component are not electrically coupled within said surface mount IC package.

14. The electronic device of claim 11 further comprising a fill material filling spaces between said at least one electronic component and adjacent portions of said encapsulating material.

15. The electronic device of claim 11 wherein said at least one electronic component comprises at least one surface mount device (SMD) component.

16. A method of making an electronic device comprising:
forming a surface mount integrated circuit (IC) package to be attached to a printed circuit board (PCB) by at least
forming an encapsulating material surrounding at least one IC and having a component receiving cavity in a bottom surface thereof to be positioned adjacent the PCB, and
coupling a plurality of electrical leads to the at least one IC and extending outwardly from the encapsulating material to be coupled to the PCB; and
coupling at least one electronic component within the component receiving cavity, the at least one electronic component comprising a plurality of electrical contacts to be coupled to the PCB.

17. The method of claim 16 further comprising forming the plurality of electrical leads to have a gull-wing shape.

18. The method of claim 16 wherein the at least one electronic component is coupled so that the plurality of electrical contacts and the plurality of electrical leads are aligned along a common seating plane.

19. The method of claim 16 wherein the at least one electronic component is coupled to extend outwardly beyond adjacent portions of the encapsulating material.

20. The method of claim 16 wherein the at least one IC and the at least one electronic component are not electrically coupled within the surface mount IC package.

21. The method of claim 16 further comprising filling spaces between the at least one electronic component and adjacent portions of the encapsulating material with a fill material.

22. The method of claim 16 further comprising forming an adhesive layer between the at least one electronic component and adjacent portions of the encapsulating material.
